(19) United States
(12) Patent Application Publication
(10) Pub. No.: US 2008/0238473 A1
(43) Pub. Date: Oct. 2, 2008

(54) Push-Pull Pulse Register Circuit

(75) Inventor: Thomas Zounes, Carlsbad, CA (US)

Correspondence Address: STMICROELECTRONICS, INC., MAIL STATION 2346, 1310 ELECTRONICS DRIVE, CARROLLTON, TX, 75006, US

(73) Assignee: STMICROELECTRONICS, INC., Carrollton, TX (US)

(21) Appl. No.: 11/691,880

(22) Filed: Mar. 27, 2007

(51) Int. Cl. H03K 19/01

(52) U.S. Cl. 326/17

(57) ABSTRACT

A push-pull pulse register circuit. The push-pull pulse register circuit includes a first logic inverter having first-inverter input and first-inverter output, a second logic inverter having second-inverter input and second-inverter output, a third logic inverter having third-inverter input and third-inverter output and configured to receive logic input data at the third-inverter input, a first logic gate having first-gate input, first-gate output, and first-gate control input, and a second logic gate having second-gate input, second-gate output, and second-gate control input. The third-inverter input is coupled to the first-gate input; the third-inverter output is coupled to the second-gate input; the second-inverter input is coupled to the second-gate output and the first-inverter output; the second-inverter output is coupled to the first-gate output and the first-inverter input; the first-gate control input is coupled to the second-gate control input; and the first-gate and the second-gate control inputs are configured to receive a clock pulse.

### BACKGROUND

Registers are high speed data storage elements located within the central processing unit (CPU) of modern computers. A register may hold various types of data such as bit sequences, individual characters, and computer instructions, as well as addresses of stored data and instructions. Data processed by the CPU is stored in a register before it is processed. For example, prior to multiplying two numbers they are both stored in registers with the final result also being stored in a register. The register typically comprises multiple individual register circuits with the number being chosen to accommodate all or a fraction of the instruction length of the computer, as well as the intended use of the register and the physical constraints of the chip on which it is to be fabricated.

The primary objective in register design is to make it fast for the CPU to access and to manipulate. Registers are fabricated on the chip itself so there is no need for a memory bus in accessing them which results in faster performance. Also, the number of registers in any given application is limited to only a few as compared with the computer's main memory. Thus, a register can be directly addressed using only a few bits. In contrast, there are often millions of words of main memory (RAM) which requires many more bits with which to specify a memory location.

The speed at which a computer is able to accomplish its assigned tasks is directly related to the speed at which its registers are able to function. The speed at which a register is able to operate is directly related to the capacitance of the clocking nodes of the register. The fewer gates that have to be clocked, the lower the capacitance that the clock has to drive with a resultant increase in the clock's potential speed. Required clock power is similarly related to the number of clocking nodes. The fewer gates that have to be clocked, the lower the required clock power.

### BRIEF DESCRIPTION OF THE DRAWINGS

The accompanying drawings provide visual representations which will be used to more fully describe various representative embodiments and can be used by those skilled in the art to better understand the representative embodiments disclosed and their inherent advantages. In these drawings, like reference numerals identify corresponding elements.

FIG. 1 is a schematic drawing of a rising edge register circuit.

FIG. 2 is a diagram of a push-pull pulse register circuit as described in various representative embodiments.

FIG. 3 is a diagram of a timing diagram for the push-pull pulse register circuit of FIG. 2.

FIG. 4 is another diagram of a push-pull pulse register circuit as described in various representative embodiments.

FIG. 5 is a flow diagram of a method for storing data in a push-pull pulse register circuit as described in various representative embodiments.

FIG. 6 is a flow diagram of another method for storing data in a push-pull pulse register circuit as described in various representative embodiments.

### DETAILED DESCRIPTION

As shown in the drawings for purposes of illustration, novel techniques are disclosed herein for a push-pull pulse register circuit. The push-pull pulse register can be implemented in a flip flop design having only one latch. Data is written into the latch during the short time the clock is in its high state. Since the register has only one latch, the design is smaller and has improved performance over the standard back to back latch type flip-flops.

In the following detailed description and in the several figures of the drawings, like elements are identified with like reference numerals.

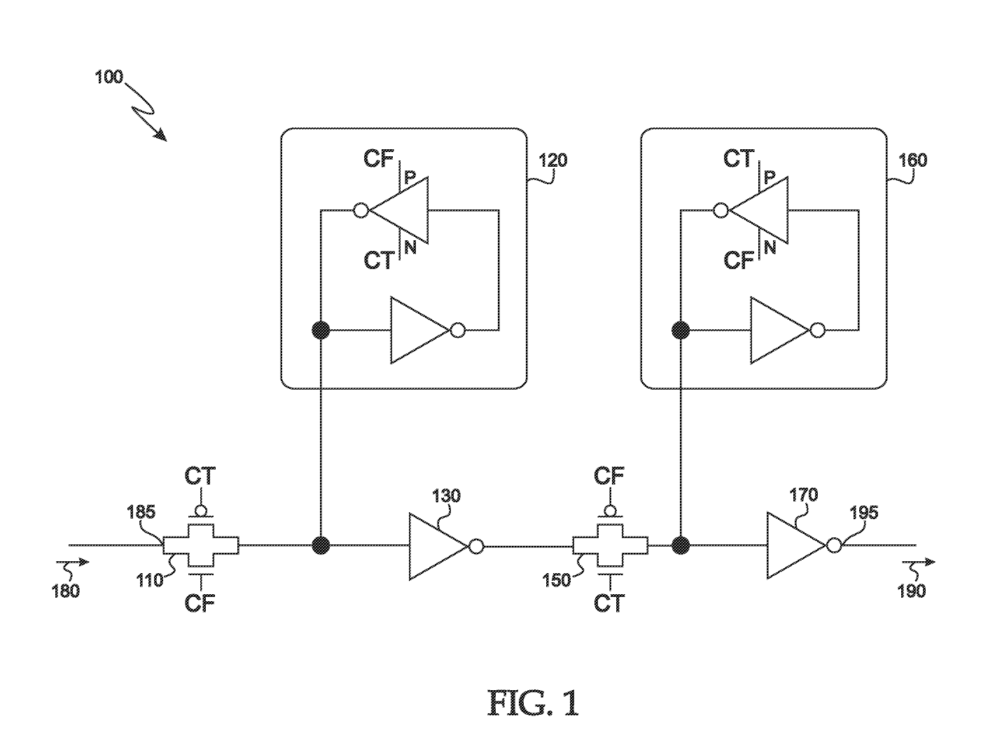

FIG. 1 is a schematic drawing of a rising edge register circuit 100. The rising edge register circuit 100 of FIG. 1 comprises a first pass gate 110, a first latch 120, an inverter 130, a second pass gate 150, a second latch 160, and an output inverter 170. The first latch 120 and the second latch 160 each comprise two back-to-back inverters. In the representative embodiment of FIG. 1, the first and the second pass gates 110,150 are CMOS pass gates. In operation, the first pass gate 110 turns on when a clock signal CT goes low. After the first pass gate 110 turns on, a rising edge input signal 180 at the rising edge register input 185 to the first pass gate 110 is transferred to the first latch 120 where it is stored. Up to this time in the cycle, the second pass gate 150 has been turned off. Then the first pass gate 110 is turned off followed by turning on the second pass gate 150. At this point the data stored in the first latch 120 is transferred to the second latch 160 until it is ready to be transferred out as rising edge output signal 190 at rising edge register output 195.

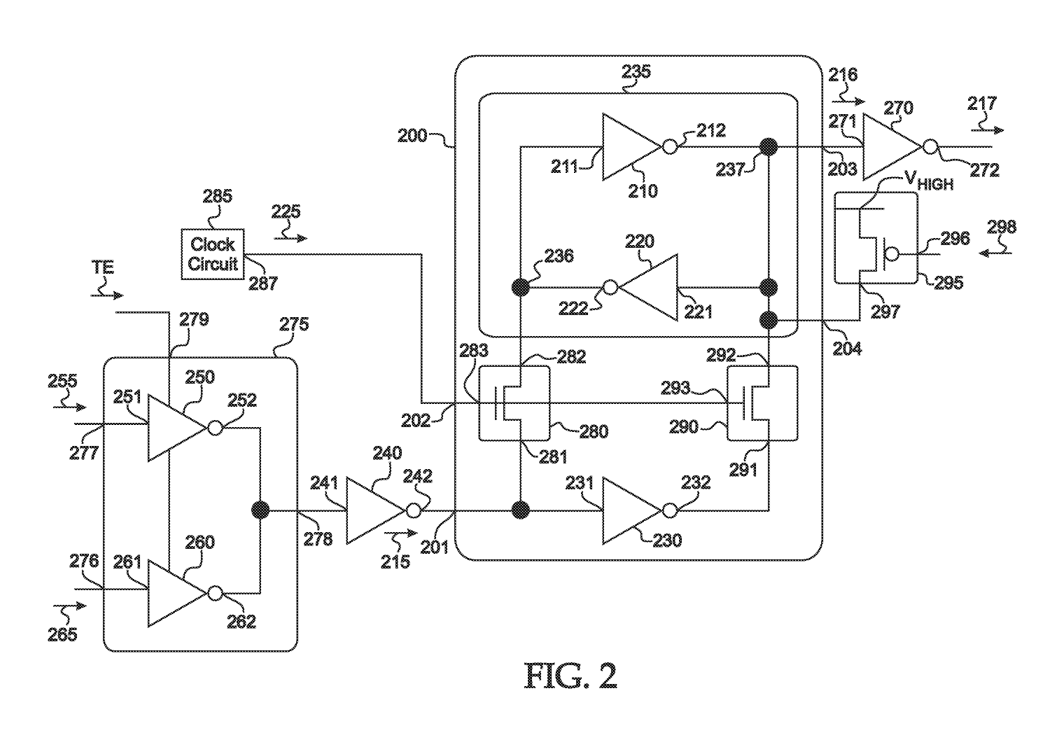

Note that in FIG. 1, eight transistors must turn on or off with each transition of the clock. Those eight transistors include two transistors each in the first and the second pass gates 110,150 and two transistors each in one of the inverters in the first and second latches 120,160. In the discussion that follows with respect to FIG. 2, it will be seen that the push-pull pulse register circuit 200 described therewith requires only two transistors to turn on or off with each transition of the clock. The fewer the number of transistors which the clock has to drive the faster the register can be and the lower the power requirement that is placed on the clock.

FIG. 2 is a diagram of a push-pull pulse register circuit 200 as described in various representative embodiments. In FIG. 2, the push-pull pulse register circuit 200 comprises a first logic inverter 210, a second logic inverter 220, a third logic inverter 230, a first logic gate 280, and a second logic gate 290. The push-pull pulse register circuit 200 has a register input 201, a register output 203, a register clock input 202, and a register reset input 204; the first logic inverter 210 has a first-inverter input 211 and a first-inverter output 212; the second logic inverter 220 has a second-inverter input 221 and a second-inverter output 222; the third logic inverter 230 has a third-inverter input 231 and a third-inverter output 232; the first logic gate 280 has a first-gate input 281, a first-gate output 282, and a first-gate control input 283; and the second logic gate 290 has a second-gate input 291, a second-gate output 292, and a second-gate control input 293.

The third-inverter input 231 is coupled to the first-gate input 281; the third-inverter output 232 is coupled to the second-gate input 291; the second-inverter input 221 is coupled to the second-gate output 292 and to the first-inverter output 212; the second-inverter output 222 is coupled to the first-gate output 282 and to the first-inverter input 211; and the first-gate control input 283 is coupled to the second-gate control input 293. In addition, the first-gate and the second-gate control inputs 283,293 are configured to receive a clock pulse 225. Latch circuit 235 comprises the combined first and second logic inverters 210,220 coupled as just described.

Also shown in FIG. 2 is a fourth logic inverter 240, an external multiplexer 275, a register clock circuit 285, a reset circuit 295, and a seventh logic inverter 270. The fourth logic inverter 240 has a fourth-inverter input 241 and a fourth-inverter output 242; the external multiplexer 275 has a first external multiplexer input 276, a second external multiplexer input 277, an external multiplexer output 278, and a test enable input 279; the register clock circuit 285 has a clock output 287; the reset circuit 295 has a reset circuit input 296 and a reset circuit output 297, and the seventh logic inverter 270 has a seventh-inverter input 271 and a seventh-inverter output 272. The seventh logic inverter 270 may also be referred to herein as output logic inverter 270; the seventh-inverter input 271 may also be referred to herein as output-inverter input 271; and the seventh-inverter output 272 may also be referred to herein as output-inverter output 272.

In the representative embodiment to FIG. 2, the first-gate and the second-gate control inputs 283,293 are coupled to the register clock input 202 which is in turn coupled to the clock output 287 of the register clock circuit 285 and receive the clock pulse 225 from the register clock circuit 285; the fourth-inverter output 242 is coupled to the register input 201 which in turn is coupled to the third-inverter input 231 and to the first-gate input 281; the fourth-inverter input 241 is coupled to the external multiplexer output 278 which in turn is coupled to the fifth-inverter output 252 and to the sixth-inverter output 262; the fifth-inverter input 251 is coupled to the second external multiplexer input 277; the sixth-inverter input 261 is coupled to the first external multiplexer input 276; the reset circuit output 297 is coupled to the register reset input 204 which in turn is coupled to second-gate output 292, to the second-inverter input 221, and to the first-inverter output 212; and the seventh-inverter input 271 is coupled to the register output 203 which in turn is coupled to the second-gate output 292, to the second-inverter input 221, and to the first-inverter output 212.

The push-pull pulse register circuit 200 is configured to receive register input data 215 at the register input 201. In other words, the third logic inverter 230 is configured to receive register input data 215 at the third-inverter input 231. The register input data 215 may also be referred to herein as logic input data 215. If a test enable signal TE is received at the test enable input 279, the fifth logic inverter 250 is turned on and the sixth logic inverter 260 is turned off. In which case, test data 255 is received at the register input 201 as the register input data 215. Otherwise, a test enable signal TE is not received at the test enable input 279, the fifth logic inverter 250 is turned off and the sixth logic inverter 260 is turned on. In which case, operational data 265 is received at the register input 201 as the register input data 215. In response to the value of the register input data 215 during the clock pulse 225, a value is set for register output data 216 at the register output 203, and the complement or inverted value of the value for the register output data 216 is set for register inverted data 217 at the seventh-inverter output 272.

If a logic “1” is received by the third-inverter input 231 at the register input 201 while the clock pulse 225 is received by the first-gate and the second-gate control inputs 283,293, the second-inverter input 221 and the coupled first-inverter output 212 are pulled down to a logic “0”, and a logic “1” is pushed onto the first-inverter input 211 and the coupled second-inverter output 222. In such case, a logic “1” is present at the seventh-inverter output 272 of the seventh logic inverter 270. Otherwise, if a logic “0” is received by the third-inverter input 231 at the register input 201 while the clock pulse 225 is received by the first-gate and the second-gate control inputs 283,293, the first-inverter input 211 and the coupled second-inverter output 222 are pulled down to a logic “0”, and a logic “1” is pushed onto the second-inverter input 221 and the coupled first-inverter output 212. In such case, a logic “0” is present at the seventh-inverter output 272 of the seventh logic inverter 270.

The register output 203 can be reset to a preselected logical state by the reset circuit 295. In the representative embodiment of FIG. 2, the reset circuit 295 comprises a p-channel MOS transistor having its source coupled to a reference potential V_{HIGH} capable of driving the second latch node 237 to the potential representing a logic “1”. When a reset signal 298 having a voltage sufficiently negative to turn on the p-channel MOS transistor is applied to its gate, the register output 203 is driven to a logic “1” which forces the second-inverter output 222 and the coupled first-inverter input 211 to a logic “0”. Another option for the reset circuit 295 is the use of an n-channel MOS transistor or other appropriate device(s). The reset circuit 295 could alternatively be coupled to the second-inverter output 222 and the first-inverter input 211 with the reset circuit 295 comprising either a p-channel MOS transistor, a n-channel MOS transistor, or other appropriate device(s). The reset circuit 295 could also comprise various combinations of the above embodiments.

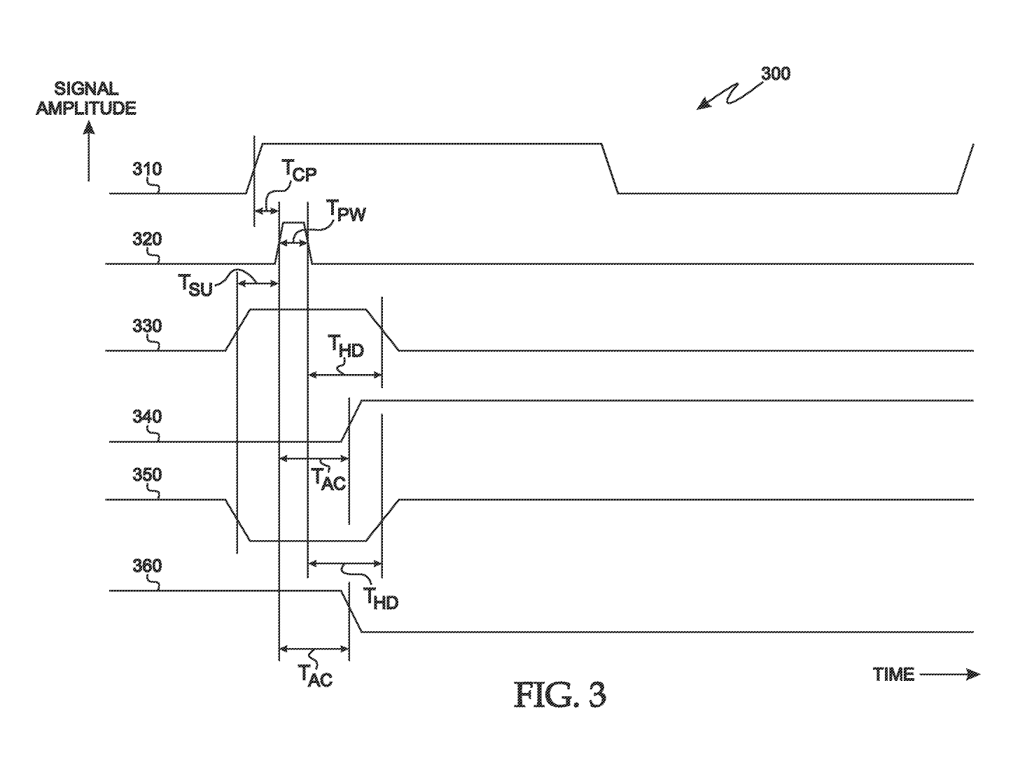

FIG. 3 is a diagram of a timing diagram 300 for the push-pull pulse register circuit 200 of FIG. 2. The timing diagram 300 of FIG. 3 shows six signals for the push-pull pulse register circuit 200 of FIG. 2. Shown from top to bottom are (1) the system clock signal 310, (2) the pulsed clock signal 320, (3) the first logic input signal 330, (4) the first logic output signal 340, (5) the second logic input signal 350, and (6) the second logic output signal 360. The leading edge mid-point of the system clock signal 310 occurs at a clock-to-pulse time T_{cp} prior to the leading edge mid-point of the pulsed clock signal 320. The pulsed clock signal 320 has a pulse width T_{PW}. The push-pull pulse register circuit 200 has been designed to require a very short clock pulse width T_{PW} for data to be written into the latch. A short pulse width T_{PW} reduces the required hold time T_{HD}.

The first logic input signal 330 and the first logic output signal 340 shown in FIG. 3, represent writing a logic “1” into the push-pull pulse register circuit 200 wherein a logic “0” had been previously stored in the push-pull register circuit 200. The leading edge mid-point of the first logic input signal 330 at the register input 201 occurs at a set-up time Tₛᵤ prior to the leading edge mid-point of the pulsed clock signal 320 at the register clock input 202, and the trailing edge mid-point of the first logic input signal 330 occurs a hold time T_{HD} after the trailing edge mid-point of the pulsed clock signal 320. The resultant value (a logic “1”) of the first logic output signal 340 can be reliably accessed at the register output 203 at a time equal to or greater than an access time T_{AC} after the leading edge mid-point of the pulsed clock signal 320.

The second logic input signal 350 and the second logic output signal 360 shown in FIG. 3, represent writing a logic “0” into the push-pull pulse register circuit 200 wherein a logic “1” had been previously stored in the push-pull register circuit 200. The leading edge mid-point of the second logic input signal 350 (the transition from a logic “1” to a logic “0”) at the register input 201 occurs a set-up time Tₛᵤ prior to the leading edge mid-point of the pulsed clock signal 320 at the register clock input 202, and the trailing edge mid-point of the second logic input signal 350 (the transition from a logic “0” to a logic “1”) occurs at a hold time T_{HD} after the trailing edge mid-point of the pulsed clock signal 320. The resultant value (a logic “0”) of the second logic output signal 360 can be reliably accessed at the register output 203 at a time equal to or greater than the access time T_{AC} after the leading edge mid-point of the pulsed clock signal 320.

In representative embodiments, the push-pull pulse register circuit 200 is a flip flop design having only one latch, the latch circuit 235 of FIG. 2. Data is written into the latch during the short time the pulsed clock signal 320 is HIGH. Since the push-pull pulse register circuit 200 has only one latch, the design is smaller and has improved performance over the standard back to back latch type flip-flops as shown in FIG. 1. The improved performance of the push-pull pulse register circuit 200 is the potential for reduced clock power and clock input loading. Simulations have shown representative embodiments of the push-pull pulse register circuit 200 to have generally better performance than the standard flip-flop found in digital, static cell libraries. The hold time T_{HD} requirement is however longer. The performance advantages of the push-pull pulse register circuit 200 is even more apparent when multiple registers are grouped together.

In addition to reducing the number of transistors coupled to the register clock and reducing the number of nodes that toggle when the register clock toggles, the key to reducing clock power in a register is to reduce the size of the transistors coupled to clock. The push-pull pulse register circuit 200 achieves all of these items. The clock output 287 is coupled to only two transistors, the first and the second logic gates 280,290. These transistors can be n-type metal-oxide semiconductor field-effect transistors (MOSFETs) which are small in size. Also, when the new data is the same as the old data, no nodes will toggle when clock toggles.

A first latch node 236 formed by the coupling of the first-inverter input 211 and the second-inverter output 222 will hold the value of the register input data 215. Whereas, a second latch node 237 formed by the coupling of the second-inverter input 221 and the first-inverter output 212 will hold the value of the complement of the register input data 215. The primary driving force in writing data into the latch circuit 235 is either from pulling down the first latch node 236 through the first logic gate 280 or from pulling down the second latch node 237 through the second logic gate 290. While the primary driving force in writing data into the latch circuit 235 is from pulling one of the latch nodes 236,237, pushing a logic “1” onto the other latch node 236,237 aids in flipping the latch circuit 235 faster. Thus, the affect is a strong pull and a moderate push. By having two forces working, one on each side of the latch, data will be written faster than it would be otherwise.

In a CMOS application, the first and the second logic gates 280,290 could be implemented as combinations of p-type and n-type MOS transistors at the cost in complexity of the register clock circuit 285. However, due to the push-pull affect in writing data into the latch circuit 235 and since a n-type MOS transistor is stronger than a p-type MOS transistor, it may be sufficient to implement the first and the second logic gates 280,290 as n-type MOS transistors.

The first and the second logic inverters 210,220 are not tri-stated as is found in a typical flip-flop register design. In such designs, one of the latch inverters usually is tri-stated in order to enable easier writes into the latch and to reduce short circuit current. However, for the push-pull pulse register circuit 200, the latch circuit 235 is symmetrical in that either side of the latch circuit 235 can be pulled down. Such functionality cannot be maintained if one of the first and second logic inverters 210,220 is tri-stated. Further, implementing the first and second logic inverters 210,220 as tri-stated devices requires an inverted clock signal with associated additional transistors. The additional transistors increase clock loading which necessitates increases in clock power and area. Also, simulations have shown that the short circuit power is insignificant compared to the total register power and is less than driving extra tri-state transistors.

The first and second logic inverters 210,220 should be sized so that they are weak enough to be overwritten but not so weak as to cause the latch nodes 236,237 to be pulled high too slowly. They should be sized at least strong enough to counteract any alpha/neutron particles that might cause soft errors. In CMOS implementations, the n-transistor in each of the first and second logic inverters 210,220 can be of small size since they do not contribute in pulling down the latch nodes 236,237 but does need to be large enough to maintain the stored data. The p-transistor in each of the first and second logic inverters 210,220 should be sized large enough to pull the latch nodes 236,237 high fast enough during a write for the new data to latch and to meet access time T_{AC} requirements.

The third and the fourth logic inverters 230,240 are used to drive data through the first and second logic gates 280,290. The third and the fourth logic inverters 230,240 need to be strong enough to pull LOW or HIGH data through the first and second logic gates 280,290. The size of the transistor gates in the first and second logic gates 280,290 also controls the speed of the write and the minimum clock pulse width needed. The sizes of the third and the fourth logic inverters 230,240 determines the set-up time Tₛᵤ and the hold time T_{HD} for the push-pull pulse register circuit 200. The external multiplexer 275 can be implemented as two tri-state inverters (fifth and sixth logic inverters 250,260). In which case, the tri-state inverters require both true and false test enable signals TE.

The reset function for the push-pull pulse register circuit 200 can be implemented in various ways in addition to that shown in FIG. 2 and described therewith. In particular, the reset circuit 295 could be implemented to write a logic “0” into the latch circuit 235 at the register output 203. Alternatively, the reset circuit 295 could be attached to the first latch node 236 and could be implemented to write a logic “1” or a logic “0’ into the latch circuit 235 at the first latch node 236.

In another representative embodiment, the register output 203 could be moved to the first latch node 236.

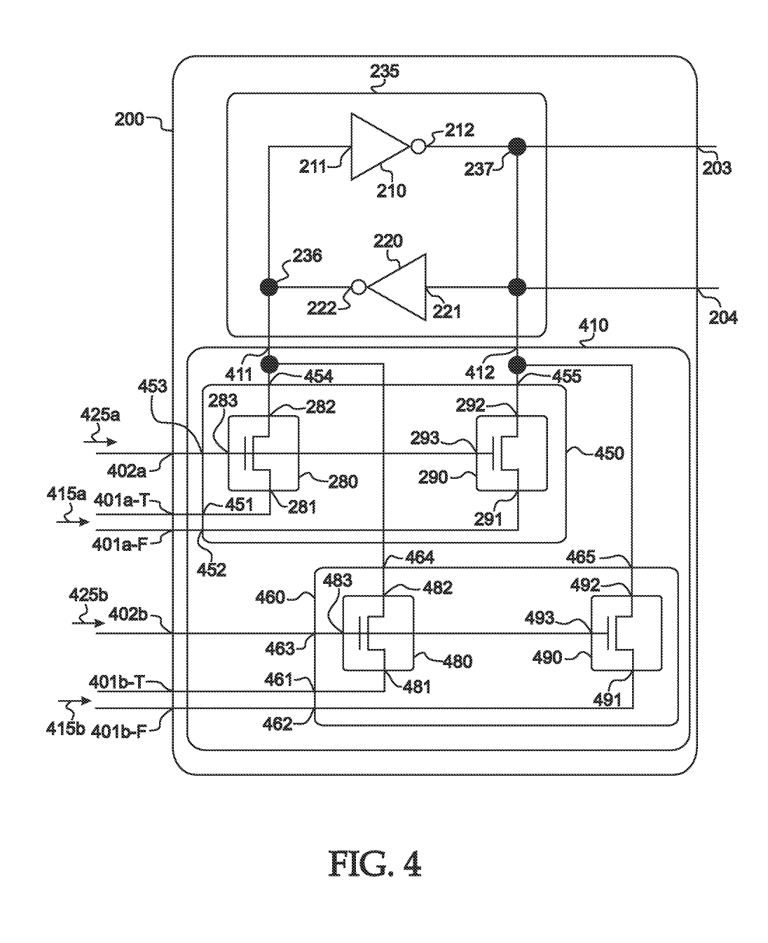

FIG. 4 is another diagram of a push-pull pulse register circuit 200 as described in various representative embodiments. In FIG. 4, the push-pull pulse register circuit 200 comprises a first logic inverter 210, a second logic inverter 220, and an internal multiplexer 410. The internal multiplexer 410 has a first internal-multiplexer output 411 and a second internal-multiplexer output 412 and comprises a first logic switch 450 and a second logic switch 460; the first logic switch 450 has a first-logic-switch first input 451, a first-logic-switch second input 452, a first-logic-switch control input 453, a first-logic-switch first output 454, and a first-logic-switch second output 455; the second logic switch 460 has a second-logic-switch first input 461, a second-logic-switch second input 462, a second-logic-switch control input 463, a second-logic-switch first output 464, and a second-logic-switch second output 465; the first logic switch 450 comprises a first logic gate 280 and a second logic gate 290; and the second logic switch 460 comprises a third logic gate 480 and a fourth logic gate 490. In FIG. 4, the push-pull pulse register circuit 200 has a first register-true input 401a-T, a first register-false input 401a-F, a second register-true input 401b-T, a second register-false input 401b-F, a first register-clock input 402a, a second register-clock input 402b, a register output 203, and a register reset input 204; the first logic inverter 210 has a first-inverter input 211 and a first-inverter output 212; the second logic inverter 220 has a second-inverter input 221 and a second-inverter output 222; the first logic gate 280 has a first-gate input 281, a first-gate output 282, and a first-gate control input 283; the second logic gate 290 has a second-gate input 291, a second-gate output 292, and a second-gate control input 293; the third logic gate 480 has a third-gate input 481, a third-gate output 482, and a third-gate control input 483; and the fourth logic gate 490 has a fourth-gate input 491, a fourth-gate output 492, and a fourth-gate control input 493.

The first-inverter input 211 is coupled to the second-inverter output 222, to the first-gate output 282 via first-logic-switch first output 454 and first internal-multiplexer output 411, and to the third-gate output 482 via second-logic-switch first output 464 and first internal-multiplexer output 411; the first-inverter output 212 is coupled to the second-inverter input 221, to the second-gate output 292 via first-logic-switch second output 455 and second internal-multiplexer output 412, to the fourth-gate output 492 via second-logic-switch second output 465 and second internal-multiplexer output 412, to the register output 203, and to the register reset input 204; the first-gate control input 283 is coupled to the second-gate control input 293 and to the first register-clock input 402a via first-logic-switch control input 453; the third-gate control input 483 is coupled to the fourth-gate control input 493 and to the second register-clock input 402b via second-logic-switch control input 463; and the first-gate input 281 is coupled to the first register-true input 401a-T via first-logic-switch first input 451; the second-gate input 291 is coupled to the first register-false input 401a-F via first-logic-switch second input 452; the third-gate input 481 is coupled to the second register-true input 401b-T via second-logic-switch first input 461; and the fourth-gate input 491 is coupled to the second register-false input 401b-F via second-logic-switch second input 462.

In addition, the first-gate and the second-gate control inputs 283,293 are configured to receive a first clock pulse 425a, and the third-gate and the fourth-gate control inputs 483,493 are configured to receive a second clock pulse 425b. Latch circuit 235 comprises the combined first and second logic inverters 210,220 coupled as just described.

The push-pull pulse register circuit 200 is configured to receive first register input data 415a in a push-pull configuration between first register-true input 401a-T and first register-false input 401a-F. The first register input data 415a may also be referred to herein as first logic value 415a at the first register-true input 401a-T and complement of the first logic value 415a at the first register-false input 401a-F. The push-pull pulse register circuit 200 is further configured to receive second register input data 415b in a push-pull configuration between second register-true input 401b-T and second register-false input 401b-F. The second register input data 415b may also be referred to herein as second logic value 415b at the second register-true input 401b-T and complement of the second logic value 415b at the second register-false input 401b-F.

In the representative embodiment of FIG. 4, the internal multiplexer 410 acts as a 2:1 multiplexer. Depending upon the status of the first clock pulse 425a or the second clock pulse 425b, either the first register input data 415a or the second register input data 415b is written into the latch circuit 235. If the first clock pulse 425a switches on, the first clock pulse 425a turns on the first and the second logic gates 280,290 enabling the first register input data 415a to be written into the latch circuit 235 in a push-pull manner. Or, if the second clock pulse 425b switches on, the second clock pulse 425b turns on the third and the fourth logic gates 480,490 enabling the second register input data 415b to be written into the latch circuit 235 in a push-pull manner.

In other representative embodiments, the internal multiplexer 410 could comprise additional logic switches in addition to the first and the second logic switches 450,460, thereby enabling register input data in addition to the first and the second register input data 415a,415b to be multiplexed into the latch circuit 235. In still another representative embodiment, the second logic switch 460 is removed from the internal multiplexer 410 effectively removing the multiplexer function and replacing the internal multiplexer 410 with the first logic switch 450.

In operation of the representative embodiment of FIG. 4, when the first clock pulse 425a is received at first register-clock input 402a, a “1” received at first register-true input 401a-T will be accompanied by a “0” at first register-false input 401a-F resulting in the first latch node 236 being forced to a “1” and the second latch node 237 being forced to a “0”, and when the first clock pulse 425a is received at first register-clock input 402a, a “0” received at first register-true input 401a-T will be accompanied by a “1” at first register-false input 401a-F resulting in the first latch node 236 being forced to a “0” and the second latch node 237 being forced to a “1”. Alternatively, when the second clock pulse 425b is received at second register-clock input 402b, a “1” received at second register-true input 401b-T will be accompanied by a “0” at second register-false input 401b-F resulting in the first latch node 236 being forced to a “1” and the second latch node 237 being forced to a “0”, and when the second clock pulse 425b is received at second register-clock input 402b, a “0” received at second register-true input 401b-T will be accompanied by a “1” at second register-false input 401b-F resulting in the first latch node 236 being forced to a “0” and the second latch node 237 being forced to a “1”.

In other representative embodiments, the internal multiplexer 410 could comprise additional logic switches in addition to the first and the second logic switches 450,460, thereby enabling register input data in addition to the first and the second register input data 415a,415b to be multiplexed into the latch circuit 235. In such representative embodiments, first logic switch 450 is generally referred to as logic switch 450, first-logic-switch first input 451 as logic-switch first input 451, first-logic-switch second input 452 as logic-switch second input 452, first-logic-switch control input 453 as logic-switch control input 453, first-logic-switch first output 454 as logic-switch first output 454, and first-logic-switch second output 455 as logic-switch second output 455. In still another representative embodiment, the second logic switch 460 is removed from the internal multiplexer 410 effectively removing the multiplexer function and replacing the internal multiplexer 410 with the first logic switch 450.

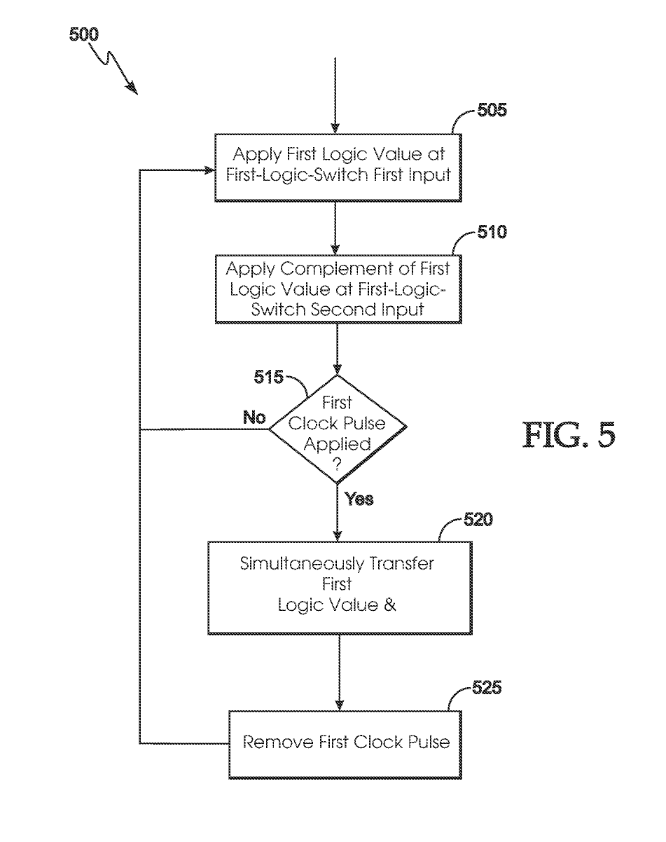

FIG. 5 is a flow diagram of a method 500 for storing data 215 in a push-pull pulse register circuit 200 as described in various representative embodiments. In block 505, a first logic value 415a is applied to the push-pull pulse register circuit 200 at a first-logic-switch first input 451. The push-pull pulse register circuit 200 comprises a first logic inverter 210 having a first-inverter input 211 and a first-inverter output 212, a second logic inverter 220 having a second-inverter input 221 coupled to the first-inverter output 212 and a second-inverter output 222 coupled to the first-inverter input 211, and a first logic switch 450 having the first-logic-switch first input 451, a first-logic-switch second input 452, a first-logic-switch control input 453, a first-logic-switch first output 454 coupled to the first-inverter input 211, and a first-logic-switch second output 455 coupled to the second-inverter input 221. Block 505 then transfers control to block 510.

In block 510, the complement of the first logic value 415a is applied to the first-logic-switch second input 452. Block 510 then transfers control to block 515.

In block 515, if a first clock pulse 425a is applied to the first-logic-switch control input 453, block 515 transfers control to block 520. Otherwise, block 515 transfers control back to block 505.

In block 520, the first logic value 415a is transferred to the first-logic-switch first output 454 and simultaneously the complement of the first logic value 415a is transferred to the first-logic-switch second output 455. Block 520 then transfers control to block 525.

In block 525, the first clock pulse 415a is removed from the first-logic-switch control input 453. Block 525 then transfers control back to block 505.

In another alternative embodiment, the push-pull pulse register circuit 200 further comprises a third logic inverter 230 having a third-inverter input 231 coupled to the first-logic-switch first input 451 and having a third-inverter output 232 coupled to the first-logic-switch second input 452, and the method step applying the complement of the first logic value 415a to the first-logic-switch second input 452 is effected by the method step applying the first logic value 415a at the first-logic-switch first input 451.

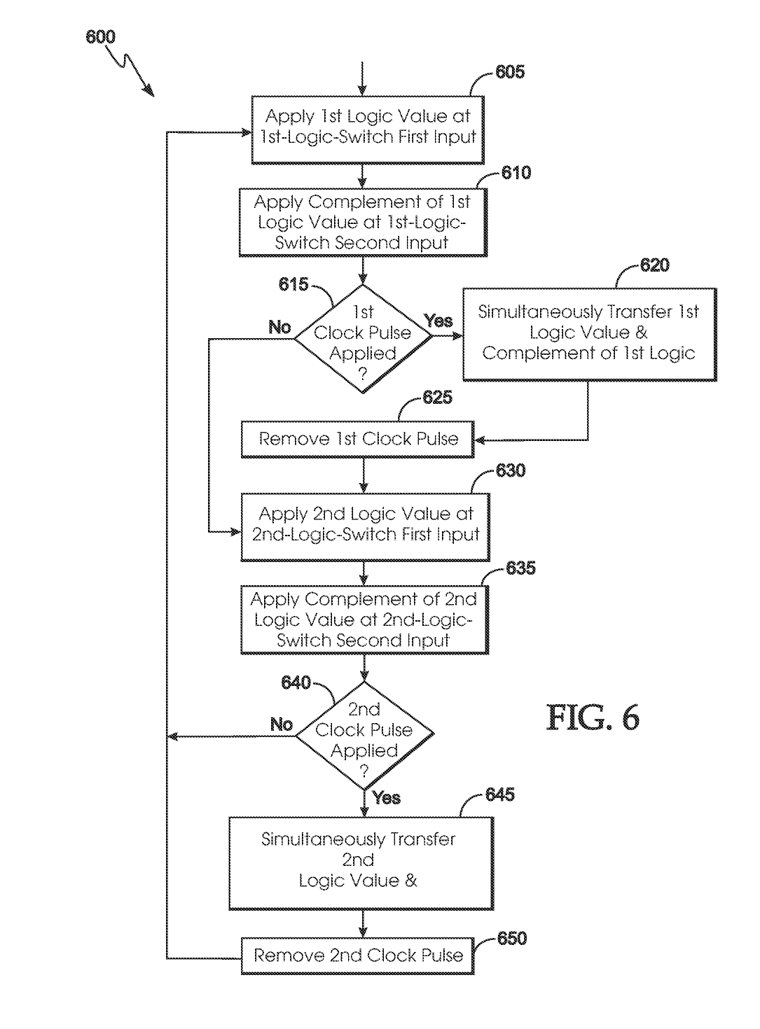

FIG. 6 is a flow diagram of another method 600 for storing data 215 in a push-pull pulse register circuit 200 as described in various representative embodiments. In block 605, a first logic value 415a is applied to the push-pull pulse register circuit 200 at a first-logic-switch first input 451. The push-pull pulse register circuit 200 comprises a first logic inverter 210 having a first-inverter input 211 and a first-inverter output 212, a second logic inverter 220 having a second-inverter input 221 coupled to the first-inverter output 212 and a second-inverter output 222 coupled to the first-inverter input 211, and a first logic switch 450 having the first-logic-switch first input 451, a first-logic-switch second input 452, a first-logic-switch control input 453, a first-logic-switch first output 454 coupled to the first-inverter input 211, and a first-logic-switch second output 455 coupled to the second-inverter input 221. Block 605 then transfers control to block 610.

In block 610, the complement of the first logic value 415a is applied to the first-logic-switch second input 452. Block 610 then transfers control to block 615.

In block 615, if a first clock pulse 425a is applied to the first-logic-switch control input 453, block 615 transfers control to block 620. Otherwise, block 615 transfers control back to block 630.

In block 620, the first logic value 415a is transferred to the first-logic-switch first output 454 and simultaneously the complement of the first logic value 415a is transferred to the first-logic-switch second output 455. Block 620 then transfers control to block 625.

In block 625, the first clock pulse 425a is removed from the first-logic-switch control input 453. Block 625 then transfers control back to block 630.

In block 630, a second logic value 415b is applied to the push-pull pulse register circuit 200 at a second-logic-switch first input 461. The push-pull pulse register circuit 200 further comprises a second logic switch 460 having the second-logic-switch first input 461, a second-logic-switch second input 462, a second-logic-switch control input 463, a second-logic-switch first output 464 coupled to the first-inverter input 211, and a second-logic-switch second output 465 coupled to the second-inverter input 221. Block 630 then transfers control to block 635.

In block 635, the complement of the second logic value 415b is applied to the second-logic-switch second input 462. Block 635 then transfers control to block 640.

In block 640, if a second clock pulse 425b is applied to the second-logic-switch control input 463, block 640 transfers control to block 645. Otherwise, block 640 transfers control back to block 605.

In block 645, the second logic value 415b is transferred to the second-logic-switch first output 464 and simultaneously the complement of the second logic value 415b is transferred to the second-logic-switch second output 465. Block 645 then transfers control to block 650.

In block 650, the second clock pulse 425b is removed from the second-logic-switch control input 463. Block 650 then transfers control back to block 605.

Other alternative embodiments could comprise additional method steps for additional logic switches 450,460 in a manner similar to that described with FIG. 6.

In representative embodiments, a push-pull pulse register circuit 200 is disclosed herein having the potential for faster switching times and lower clock driving power than the more standard back to back latch type flip-flops. The push-pull pulse register circuit 200 can be implemented in a flip flop design having only one latch. Data is written into the latch during the short time clock is in its high state. Since the register has only one latch, the design can be smaller with the resultant improved performance.

The representative embodiments, which have been described in detail herein, have been presented by way of example and not by way of limitation. It will be understood by those skilled in the art that various changes may be made in the form and details of the described embodiments resulting in equivalent embodiments that remain within the scope of the appended claims.

What is claimed is:

1. A push-pull pulse register circuit, comprising:
a first logic inverter having a first-inverter input and a first-inverter output;
a second logic inverter having a second-inverter input and a second-inverter output;
a third logic inverter having a third-inverter input and a third-inverter output and configured to receive logic input data at the third-inverter input;
a first logic gate having a first-gate input, a first-gate output, and a first-gate control input; and
a second logic gate having a second-gate input, a second-gate output, and a second-gate control input, wherein the third-inverter input is coupled to the first-gate input, wherein the third-inverter output is coupled to the second-gate input, wherein the second-inverter input is coupled to the second-gate output and the first-inverter output, wherein the second-inverter output is coupled to the first-gate output and the first-inverter input, wherein the first-gate control input is coupled to the second-gate control input, and wherein the first-gate and the second-gate control inputs are configured to receive a clock pulse.

2. The push-pull pulse register circuit as recited in claim 1, wherein a second latch node comprises the coupled second-inverter input, second-gate output and first-inverter output and wherein the second latch node is configured for outputting the value of the second latch node.

3. The push-pull pulse register circuit as recited in claim 2, further comprising:
a seventh logic inverter having a seventh-inverter input and a seventh-inverter output, wherein the seventh-inverter input is attached to the second latch node and wherein the seventh-inverter output is configured for outputting complement of the value of the second latch node.

4. The push-pull pulse register circuit as recited in claim 1, wherein a first latch node comprises the coupled first-inverter input, first-gate output and second-inverter output and wherein the first latch node is configured for outputting the value of the first latch node.

5. The push-pull pulse register circuit as recited in claim 4, further comprising:
a seventh logic inverter having a seventh-inverter input and a seventh-inverter output, wherein the seventh-inverter input is attached to the first latch node and wherein the seventh-inverter output is configured for outputting complement of the value of the first latch node.

6. The push-pull pulse register circuit as recited in claim 1, further comprising:
a fourth logic inverter having a fourth-inverter input and a fourth-inverter output, wherein the fourth-inverter output is attached to the third-inverter input and wherein the fourth-inverter input is configured to receive the complement of the logic input data that the third-inverter input is configured to receive.

7. The push-pull pulse register circuit as recited in claim 1, further comprising:
an external multiplexer having a first external multiplexer input, a second external multiplexer input, a test enable input, and an external multiplexer output, wherein the external multiplexer output is attached to the third-inverter input, wherein the first external multiplexer input is configured to receive operational data, wherein the second external multiplexer input is configured to receive test data, and
wherein if the test enable input receives a test enable signal:
operational data at the first external multiplexer input is the complement of the logic input data that the third-inverter input receives,
otherwise:
test data at the second external multiplexer input is the complement of the logic input data that the third-inverter input receives.

8. A push-pull pulse register circuit, comprising:
a first logic inverter having a first-inverter input and a first-inverter output;
a second logic inverter having a second-inverter input and a second-inverter output; and
an internal multiplexer having a first register-clock input, a second register-clock input, a first register-true input, a first register-false input, a second register-true input, a second register-false input, a first internal-multiplexer output, and a second internal-multiplexer output, wherein the first internal-multiplexer output is coupled to the first-inverter input and the second-inverter output, wherein the second internal-multiplexer output is coupled to the first-inverter output and the second-inverter input, wherein if a first clock pulse is received on the first register-clock input, a first logic value at the first register-true input is transferred to the first internal-multiplexer output and complement of the first logic value is transferred from the first register-false input to the second internal-multiplexer output, and wherein if a second clock pulse is received on the second register-clock input, a second logic value at the second register-true input is transferred to the first internal-multiplexer output and complement of the second logic value is transferred from the second register-false input to the second internal-multiplexer output.

9. The push-pull pulse register circuit as recited in claim 8, wherein a second latch node comprises the coupled first-inverter output and second-inverter input and wherein the second latch node is configured for outputting the value of the second latch node.

10. The push-pull pulse register circuit as recited in claim 9, further comprising:
an output logic inverter having an output-inverter input and an output-inverter output, wherein the output-inverter input is attached to the second latch node and wherein the output-inverter output is configured for outputting complement of the value of the second latch node.

11. The push-pull pulse register circuit as recited in claim 8, wherein a first latch node comprises the coupled first-inverter input and second-inverter output and wherein the first latch node is configured for outputting the value of the first latch node.

12. The push-pull pulse register circuit as recited in claim 11, further comprising:
an output logic inverter having an output-inverter input and an output-inverter output, wherein the output-inverter input is attached to the first latch node and wherein the output-inverter output is configured for outputting complement of the value of the first latch node.

13. The push-pull pulse register circuit as recited in claim 8, wherein the internal multiplexer comprises:
a first logic switch having a first-logic-switch first input, a first-logic-switch second input, a first-logic-switch control input, a first-logic-switch first output, and a first-logic-switch second output, wherein the first-logic-switch first input is coupled to the first register-true input, wherein the first-logic-switch second input is coupled to the first register-false input, wherein the first-logic-switch control input is coupled to the first register-clock input, wherein the first-logic-switch first output is coupled to first internal-multiplexer output, and wherein the first-logic-switch second output is coupled to second internal-multiplexer output; and
a second logic switch having a second-logic-switch first input, a second-logic-switch second input, a second-logic-switch control input, a second-logic-switch first output, and a second-logic-switch second output, wherein the second-logic-switch first input is coupled to the second register-true input, wherein the second-logic-switch second input is coupled to the second register-false input, wherein the second-logic-switch control input is coupled to the second register-clock input, wherein the second-logic-switch first output is coupled to first internal-multiplexer output, and wherein the second-logic-switch second output is coupled to second internal-multiplexer output.

14. The push-pull pulse register circuit as recited in claim 13,
wherein the first logic switch comprises:
a first logic gate having a first-gate input, a first-gate output, and a first-gate control input, wherein the first-gate input is coupled to the first-logic-switch first input, wherein the first-gate output is coupled to first-logic-switch first output, and wherein the first-gate control input is coupled to first-logic-switch control input; and
a second logic gate having a second-gate input, a second-gate output, and a second-gate control input, wherein the second-gate input is coupled to first-logic-switch second input, wherein the second-gate output is coupled to first-logic-switch second output, and wherein the second-gate control input is coupled to first-logic-switch control input; and
wherein the second logic switch comprises:
a third logic gate having a third-gate input, a third-gate output, and a third-gate control input, wherein the third-gate input is coupled to second-logic-switch first input, wherein the third-gate output is coupled to second-logic-switch first output, and wherein the third-gate control input is coupled to second-logic-switch control input; and
a fourth logic gate having a fourth-gate input, a fourth-gate output, and a fourth-gate control input, wherein the fourth-gate input is coupled to second-logic-switch second input, wherein the fourth-gate output is coupled to second-logic-switch second output, and wherein the fourth-gate control input is coupled to second-logic-switch control input.

15. The push-pull pulse register circuit as recited in claim 8, wherein the internal multiplexer further comprises:
at least one additional register-clock input;
one register-true input and one register-false input associated with each additional register-clock input, wherein if an additional clock pulse is received on one additional register-clock input, a logic value at the associated register-true input is transferred to the first internal-multiplexer output and complement of the logic value is transferred from the associated register-false input to the second internal-multiplexer output.

16. The push-pull pulse register circuit as recited in claim 15, wherein the internal multiplexer comprises:
a logic switch associated with each register-clock input, wherein each logic switch has a logic-switch first input, a logic-switch second input, a logic-switch control input, a logic-switch first output, and a logic-switch second output, wherein each logic-switch first input is coupled to the associated register-true input, wherein each logic-switch second input is coupled to the associated register-false input, wherein each logic-switch control input is coupled to the associated register-clock input, wherein each logic-switch first output is coupled to first internal-multiplexer output, and wherein each logic-switch second output is coupled to second internal-multiplexer output.

17. The push-pull pulse register circuit as recited in claim 16, wherein each logic switch comprises:
a first logic gate having a first-gate input, a first-gate output, and a first-gate control input, wherein for each logic switch the first-gate input is coupled to the logic-switch first input of its logic switch, wherein for each logic switch the first-gate output is coupled to the logic-switch first output of its logic switch, and wherein for each logic switch the first-gate control input is coupled to logic-switch control input of its logic switch; and
a second logic gate having a second-gate input, a second-gate output, and a second-gate control input, wherein for each logic switch the second-gate input is coupled to logic-switch second input of its logic switch, wherein for each logic switch the second-gate output is coupled to the logic-switch second output of its logic switch, and wherein for each logic switch the second-gate control input is coupled to logic-switch control input of its logic switch.

18. A method for storing data in a push-pull pulse register circuit, comprising:
applying a first logic value to the push-pull pulse register circuit at a first-logic-switch first input, wherein the push-pull pulse register circuit comprises
a first logic inverter having a first-inverter input and a first-inverter output,
a second logic inverter having a second-inverter input coupled to the first-inverter output and a second-inverter output coupled to the first-inverter input, and
a first logic switch having the first-logic-switch first input, a first-logic-switch second input, a first-logic-switch control input, a first-logic-switch first output coupled to the first-inverter input, and a first-logic-switch second output coupled to the second-inverter input;
applying the complement of the first logic value to the first-logic-switch second input; and
if a first clock pulse is applied to the first-logic-switch control input, transferring the first logic value to the first-logic-switch first output and simultaneously transferring the complement of the first logic value to the first-logic-switch second output.

19. The method as recited in claim 18, further comprising:
applying a second logic value to the push-pull pulse register circuit at a second-logic-switch first input, wherein the push-pull pulse register circuit further comprises:
a second logic switch having the second-logic-switch first input, a second-logic-switch second input, a second-logic-switch control input, a second-logic-switch first output coupled to the first-inverter input, and a second-logic-switch second output coupled to the second-inverter input;
applying the complement of the second logic value to the second-logic-switch second input; and
if a second clock pulse is applied to the second-logic-switch control input, transferring the second logic value to the second-logic-switch first output and simultaneously transferring the complement of the second logic value to the second-logic-switch second output.

20. The method as recited in claim 18, wherein the push-pull pulse register circuit further comprises a third logic inverter having a third-inverter input coupled to the first-logic-switch first input and having a third-inverter output coupled to the first-logic-switch second input and wherein the method step applying the complement of the first logic value to the first-logic-switch second input is effected by the method step applying the first logic value at the first-logic-switch first input.
